(19) United States
(12) Patent Application Publication
(10) Pub. No.: US 2011/0215473 A1
(43) Pub. Date: Sep. 8, 2011

(54) SEMICONDUCTOR DEVICE AND METHOD FOR MANUFACTURING SAME

(75) Inventors: Mitsuhiko Noda, Kanagawa-ken (JP); Mitsuhiro Noguchi, Kanagawa-ken (JP); Kenichi Fujii, Mie-ken (JP); Fumitaka Arai, Kanagawa-ken (JP)

(73) Assignee: Kabushiki Kaisha Toshiba, Tokyo (JP)

(21) Appl. No.: 12/886,133

(22) Filed: Sep. 20, 2010

(30) Foreign Application Priority Data
Mar. 8, 2010 (JP) 2010-050479

(51) Int. Cl. H01L 23/532; H01L 21/768

(52) U.S. Cl. 257/750; 438/653; 257/E23.161; 257/E21.584

(57) ABSTRACT

According to one embodiment, a semiconductor device includes a first contact, a second contact, and an intermediate interconnection. The first contact is made of a first conductive material. The second contact is made of a second conductive material. A lower end portion of the second contact is connected to an upper end portion of the first contact. The intermediate interconnection is made of a third conductive material and isolated from the first contact and the second contact. A lower face of the intermediate interconnection is positioned higher than a lower face of the first contact. An upper face of the intermediate interconnection is positioned lower than an upper face of the second contact. A diffusion coefficient of the first conductive material with respect to the second conductive material is lower than a diffusion coefficient of the third conductive material with respect to the second conductive material.

### CROSS-REFERENCE TO RELATED APPLICATIONS

This application is based upon and claims the benefit of priority from the prior Japanese Patent Application No. 2010-050479, filed on Mar. 8, 2010; the entire contents of which are incorporated herein by reference.

### FIELD

Embodiments described herein relate generally to a semiconductor device and method for manufacturing the same.

### BACKGROUND

Conventionally, NAND flash memory has been developed as a nonvolatile semiconductor memory device. In NAND flash memory, multiple active areas aligned in one direction are formed in the upper layer portion of a silicon substrate. Multiple control gate electrodes aligned in another direction are disposed on the silicon substrate. By providing floating gate electrodes at each intersection between the active areas and the control gate electrodes, multiple memory cells are arranged in a matrix configuration. The writing, reading, and erasing of data of the memory cells are performed by controlling the potentials of the control gate electrodes and controlling the potentials of the active areas via source lines and bit lines.

An inter-layer insulating film is provided on the silicon substrate to bury the control gate electrodes, the source lines, and the bit lines; and a shunt interconnection is provided on the inter-layer insulating film. The shunt interconnection is connected to the silicon substrate via an upper contact, an intermediate interconnection, and a lower contact formed in the inter-layer insulating film. Thereby, the shunt interconnection can apply a prescribed potential to the silicon substrate (for instance, refer to JP-A 2009-187988 (Kokai)).

In such a NAND flash memory, high integration of the memory cells can be realized and the device can be shrunk by arranging the memory cells in a matrix configuration.

### BRIEF DESCRIPTION OF THE DRAWINGS

FIGS. 1A to 1D are cross-sectional views of semiconductor devices according to a first embodiment and a comparative example thereof;

FIG. 2 is a schematic plan view of a semiconductor device according to a second embodiment;

FIG. 3A is a plan view of a portion of a memory cell array of the semiconductor device according to the second embodiment, FIG. 3B is a cross-sectional view along line A-A′ of FIG. 3A, and FIG. 3C is a cross-sectional view along line B-B′ of FIG. 3A;

FIG. 4A is a plan view of another portion of the memory cell array of the semiconductor device according to the second embodiment, FIG. 4B is a cross-sectional view along line A-A′ of FIG. 4A, and FIG. 4C is a cross-sectional view along line B-B′ of FIG. 4A;

FIG. 5A is a plan view of a portion of a peripheral circuit of the semiconductor device according to the second embodiment and FIG. 5B is a cross-sectional view along line C-C′ of FIG. 5A;

FIG. 6 is a cross-sectional view of processes of a method for manufacturing the semiconductor device according to the second embodiment;

FIG. 7 is a cross-sectional view of processes of the method for manufacturing the semiconductor device according to the second embodiment;

FIG. 8 is a cross-sectional view of processes of the method for manufacturing the semiconductor device according to the second embodiment;

FIG. 9 is a cross-sectional view of processes of the method for manufacturing the semiconductor device according to the second embodiment;

FIG. 10 is a cross-sectional view of processes of the method for manufacturing the semiconductor device according to the second embodiment;

FIG. 11 is a cross-sectional view of processes of the method for manufacturing the semiconductor device according to the second embodiment;

FIG. 12 is a cross-sectional view of processes of the method for manufacturing the semiconductor device according to the second embodiment;

FIG. 13 is a cross-sectional view of processes of the method for manufacturing the semiconductor device according to the second embodiment;

FIG. 14 is a cross-sectional view of processes of the method for manufacturing the semiconductor device according to the second embodiment;

FIG. 15 is a cross-sectional view of processes of the method for manufacturing the semiconductor device according to the second embodiment;

FIG. 16 is a cross-sectional view of processes of the method for manufacturing the semiconductor device according to the second embodiment;

FIG. 17 is a cross-sectional view of processes of the method for manufacturing the semiconductor device according to the second embodiment;

FIG. 18 is a cross-sectional view of processes of the method for manufacturing the semiconductor device according to the second embodiment;

FIGS. 19A to 19D are cross-sectional views of processes of the method for manufacturing the semiconductor device according to the second embodiment in the case where the formation region of a contact of the upper level is shifted from the region directly above a contact of the lower level;

FIG. 20 is a cross-sectional view of processes of a method for manufacturing a semiconductor device according to a third embodiment;

FIG. 21 is a cross-sectional view of processes of the method for manufacturing the semiconductor device according to the third embodiment; and

FIG. 22 is a cross-sectional view of processes of the method for manufacturing the semiconductor device according to the third embodiment.

### DETAILED DESCRIPTION

In general, according to one embodiment, a semiconductor device includes a first contact, a second contact, and an intermediate interconnection. The first contact is made of a first conductive material. The second contact is made of a second conductive material. A lower end portion of the second contact is connected to an upper end portion of the first contact. The intermediate interconnection is made of a third conductive material and isolated from the first contact and the second contact. A lower face of the intermediate interconnection is positioned higher than a lower face of the first contact. An upper face of the intermediate interconnection is positioned lower than an upper face of the second contact. A diffusion coefficient of the first conductive material with respect to the second conductive material is lower than a diffusion coefficient of the third conductive material with respect to the second conductive material.

According to another embodiment, a semiconductor device includes a first contact, a second contact, and an intermediate interconnection. The first contact is made of tungsten. The second contact is made of aluminum. A lower end portion of the second contact is connected to an upper end portion of the first contact. The intermediate interconnection is made of copper and isolated from the first contact and the second contact. A lower face of the intermediate interconnection is positioned higher than a lower face of the first contact. An upper face of the intermediate interconnection is positioned lower than an upper face of the second contact.

According to still another embodiment, a method for manufacturing a semiconductor device is disclosed. The method can form a first contact made of a first conductive material in a first insulating film, form a second insulating film on the first insulating film, form an intermediate interconnection made of a third conductive material in a portion of the second insulating film isolated from a region directly above the first contact, form a third insulating film on the second insulating film, and form a second contact made of a second conductive material in a portion of the second insulating film and the third insulating film including a region directly above the first contact. A diffusion coefficient of the first conductive material with respect to the second conductive material is lower than a diffusion coefficient of the third conductive material with respect to the second conductive material.

Exemplary embodiments of the invention will now be described with reference to the drawings.

First, a first embodiment of the invention will be described.

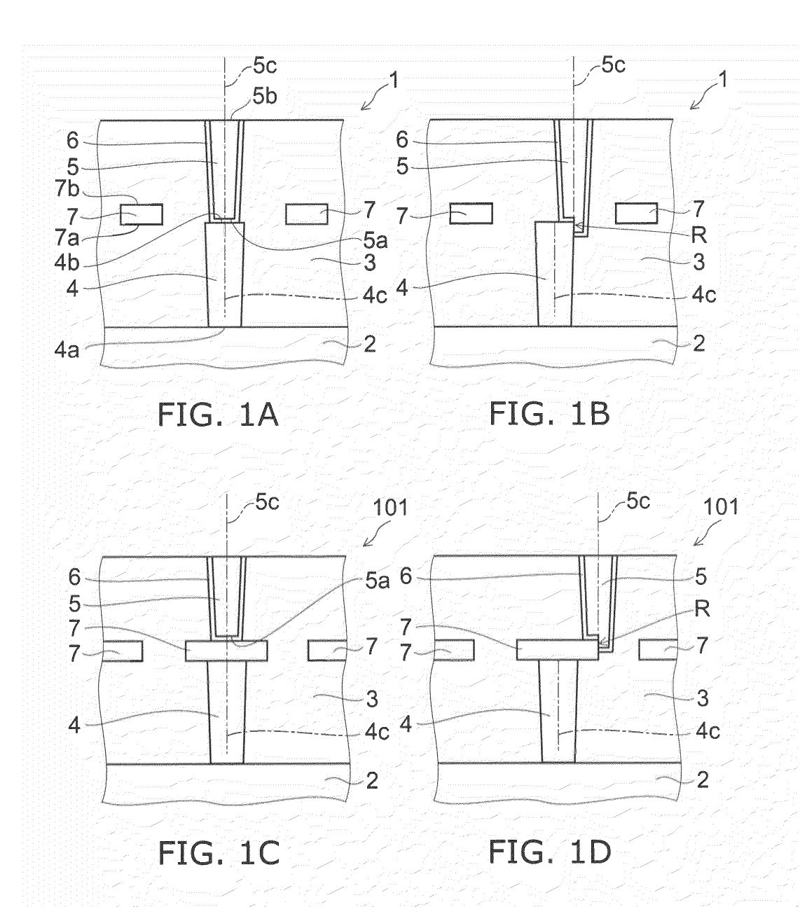

FIGS. 1A to 1D are cross-sectional views illustrating semiconductor devices according to this embodiment and a comparative example thereof. FIG. 1A illustrates this embodiment in the case where the contacts are not shifted from each other. FIG. 1B illustrates this embodiment in the case where the contacts are shifted from each other. FIG. 1C illustrates the comparative example in the case where the contacts are not shifted from each other. FIG. 1D illustrates the comparative example in the case where the contacts are shifted from each other.

In a semiconductor device 1 according to this embodiment as illustrated in FIGS. 1A and 1B, an inter-layer insulating film 3 is provided on a semiconductor substrate 2; and two levels of contacts 4 and 5 are provided in the inter-layer insulating film 3. The lower end portion of the contact 4 disposed on the lower level side is connected to the semiconductor substrate 2. The contact 5 disposed on the upper level side is provided in a region directly above the contact 4; and the lower end portion of the contact 5 is connected to the upper end portion of the contact 4. A barrier metal layer 6 is formed on the lower face of the contact 5 and on the side faces of the contact 5. An intermediate interconnection 7 is provided in the inter-layer insulating film 3. The position of the intermediate interconnection 7 in the vertical direction is about between the contact 4 and the contact 5. In other words, a lower face 7a of the intermediate interconnection 7 is positioned higher than a lower face 4a of the contact 4 of the lower level; and an upper face 7b of the intermediate interconnection 7 is positioned lower than an upper face 5b of the contact 5 of the upper level. For example, the lower face 7a of the intermediate interconnection 7 is substantially the same height as an upper face 4b of the contact 4. In this embodiment, the intermediate interconnection 7 is not interposed between the contact 4 and the contact 5 and is isolated from the contacts 4 and 5.

The diffusion coefficient of the conductive material of the contact 4 with respect to the conductive material of the contact 5 is lower than the diffusion coefficient of the conductive material of the intermediate interconnection 7 with respect to the conductive material of the contact 5. For example, the contact 4 is formed of tungsten (W), the contact 5 is formed of aluminum (Al), and the intermediate interconnection 7 is formed of copper (Cu). In such a case, the diffusion coefficient of tungsten with respect to aluminum is lower than the diffusion coefficient of copper with respect to aluminum. For example, at a temperature of 450° C., the diffusion coefficient of copper with respect to aluminum is 5×10⁻¹⁰° [cm²/sec] while the diffusion coefficient of tungsten with respect to aluminum is substantially zero. In other words, an alloy of aluminum and tungsten is not formed. For example, the barrier metal layer 6 is formed of tantalum (Ta), tantalum nitride (TaN), titanium (Ti), or titanium nitride (TiN); the semiconductor substrate 2 is formed of silicon (Si); and the inter-layer insulating film 3 is formed of silicon oxide (SiO₂).

In the semiconductor device 1 as illustrated in FIG. 1A, in the case where the shift amount of a central axis 5c of the contact 5 from a central axis 4c of the contact 4 is small and the entire region of a lower face 5a of the contact 5 is disposed in a region directly above the upper face 4b of the contact 4, the entire region of the lower face 5a of the contact 5 contacts the upper face of the barrier metal layer 6; and the lower face of the barrier metal layer 6 contacts the upper face 4b of the contact 4. In such a case, the barrier metal layer 6 is interposed between the contact 4 and the contact 5 and prevents diffusion of the tungsten of the contact 4 and the aluminum of the contact 5. Therefore, voids do not occur in the contact 4 due to diffusion of the tungsten; and high-resistance intermetallic compounds are not formed. Accordingly, the resistance between the contact 4 and the contact 5 does not increase.

On one hand, as illustrated in FIG. 1B, in the case where the shift amount of the central axis 5c of the contact 5 from the central axis 4c of the contact 4 is large, only a portion of the contact 5 is disposed in a region directly above the contact 4; and the remaining portion juts into a region outside the region directly above the contact 4 and extends around to the side of the contact 4. On the other hand, when the barrier metal layer 6 is deposited, the barrier metal layer 6 does not easily extend around onto the side face of the contact 4. Therefore, a region R of the side face of the contact 4 is not covered with the barrier metal layer 6. As a result, the side face of the portion of the contact 5 that juts from the region directly above the contact 4 contacts the side face of the contact 4 at the region R. Thereby, the tungsten of the contact 4 directly contacts the aluminum of the contact 5. However, because the diffusion coefficient of tungsten with respect to aluminum is relatively low, the amount of tungsten diffusing into the contact 5 is small. Therefore, voids substantially do not occur in the contact 4; inter-metallic compounds are not substantially formed; and the resistance between the contact 4 and the contact 5 substantially does not increase.

Conversely, as illustrated in FIGS. 1C and 1D, a semiconductor device 101 according to the comparative example differs from the semiconductor device 1 according to this embodiment in that the intermediate interconnection 7 is disposed between the contact 4 and the contact 5 and the contact 5 is connected to the contact 4 via the intermediate interconnection 7.

In the semiconductor device 101 as illustrated in FIG. 1C, in the case where the shift amount of the central axis 5c of the contact 5 from the central axis 4c of the contact 4 is relatively small and the entire region of the lower face 5a of the contact 5 is disposed in a region directly above the intermediate interconnection 7, the contact 5 is connected to the intermediate interconnection 7 via the barrier metal layer 6. In such a case, the barrier metal layer 6 functions as a diffusion prevention layer to prevent diffusion of the copper of the intermediate interconnection 7 and the aluminum of the contact 5. Therefore, voids do not occur in the intermediate interconnection 7 due to the copper diffusing into the aluminum; and high-resistance intermetallic compounds are not formed. Accordingly, the resistance between the intermediate interconnection 7 and the contact 5 does not increase; and the resistance between the contact 4 and the contact 5 does not increase.

However, as illustrated in FIG. 1D, the remaining portion of the contact 5 extends around to the side of the intermediate interconnection 7 in the case where the shift amount of the central axis 5c of the contact 5 from the central axis 4c of the contact 4 is relatively large, only a portion of the contact 5 is disposed in the region directly above the intermediate interconnection 7, and the remaining portion of the contact 5 is disposed in a region outside the region directly above the intermediate interconnection 7. On the other hand, the barrier metal layer 6 does not easily extend around to the side face of the intermediate interconnection 7 when the barrier metal layer 6 is deposited. Therefore, the region R of the side face of the intermediate interconnection 7 is not covered with the barrier metal layer 6. As a result, the portion of the contact 5 jutting from the region directly above the intermediate interconnection 7 contacts the region R of the side face of the contact 4; and the copper of the intermediate interconnection 7 directly contacts the aluminum of the contact 5. In such a case, the diffusion coefficient of copper with respect to aluminum is relatively high. Therefore, voids undesirably occur in the intermediate interconnection 7 due to diffusion of the copper into the aluminum; the copper reacts with the aluminum of the contact 5 to undesirably form a high-resistance intermetallic compound, e.g., AlCu; and the resistance between the intermediate interconnection 7 and the contact 5 increases. As a result, the resistance between the contact 4 and the contact 5 increases.

By making the intermediate interconnection 7 sufficiently wide as viewed from above, the position where the contact 5 is disposed does not move outside the region directly above the intermediate interconnection 7; and the resistance increase due to the contact 5 contacting the side face of the intermediate interconnection 7 can be prevented. However, because the surface area of the intermediate interconnection 7 increases in such a case, shrinking of the semiconductor device 101 is obstructed. Conversely, according to this embodiment, an intermediate interconnection 7 having a width wider than the contact 4 as viewed from above is not provided between the contact 4 and the contact 5. Therefore, downsizing of the semiconductor device 1 is possible.

Thus, according to this embodiment, the resistance increase between the contact 4 and the contact 5 can be prevented and the semiconductor device 1 can be shrunk by eliminating the intermediate interconnection 7 having a width wider than the contact 4 as viewed from above from between the contact 4 and the contact 5 and by the diffusion coefficient of the conductive material (e.g., tungsten) of the contact 4 with respect to the conductive material (e.g., aluminum) of the contact 5 being lower than the diffusion coefficient of the conductive material (e.g., copper) of the intermediate interconnection 7 with respect to the conductive material (e.g., aluminum) of the contact 5.

A second embodiment of the invention will now be described.

This embodiment is an example in which the first embodiment described above is applied to a NAND flash memory.

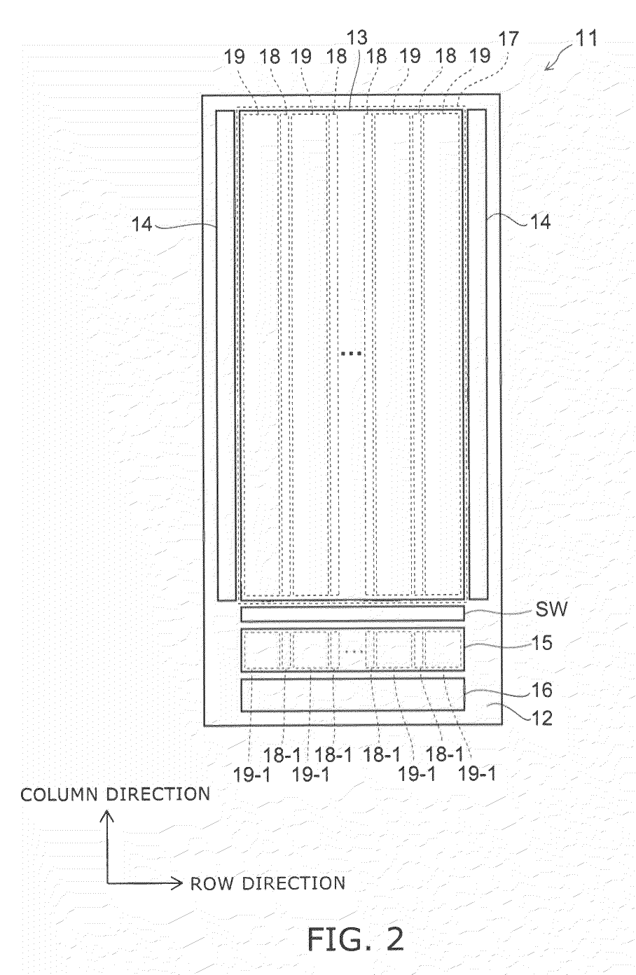

FIG. 2 is a schematic plan view illustrating a semiconductor device according to this embodiment.

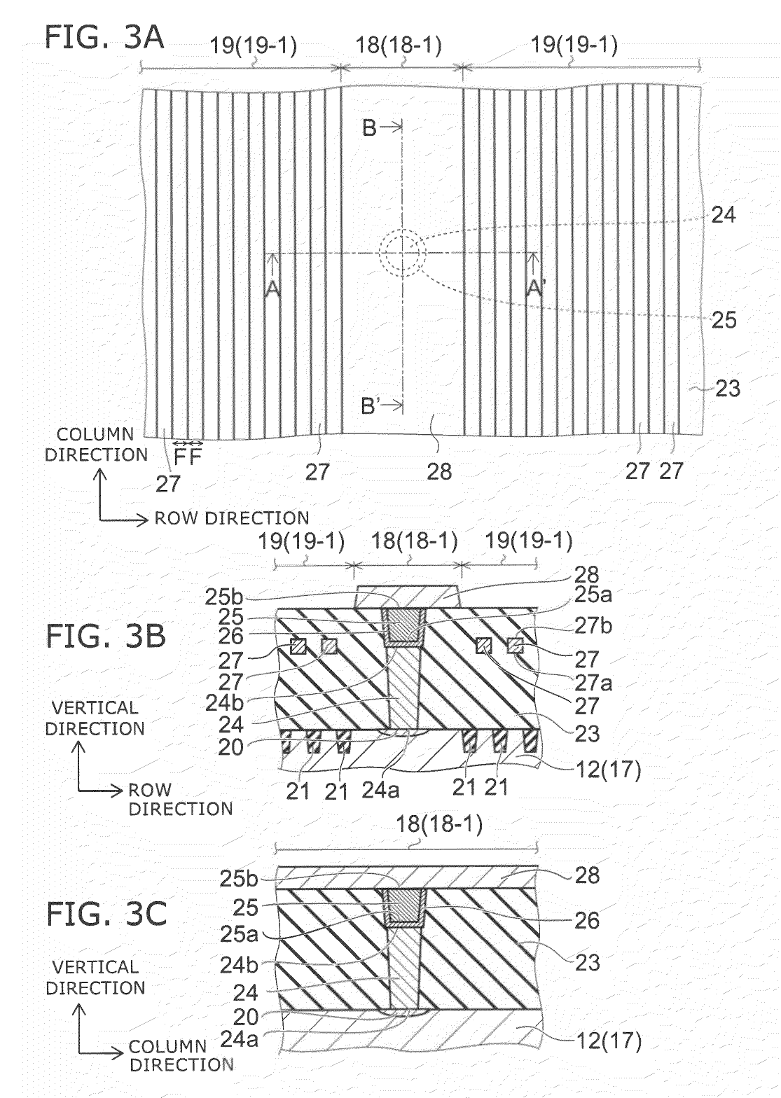

FIG. 3A is a plan view illustrating a portion of a memory cell array of the semiconductor device according to this embodiment. FIG. 3B is a cross-sectional view along line A-A′ of FIG. 3A. FIG. 3C is a cross-sectional view along line B-B′ of FIG. 3A.

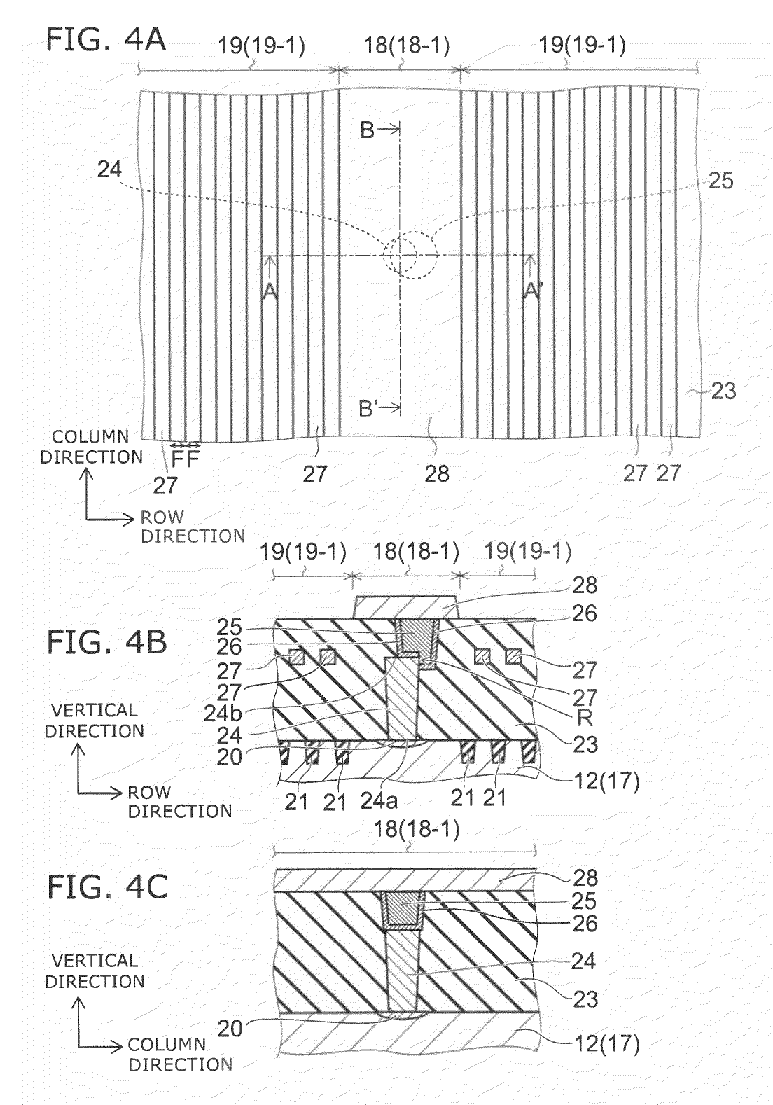

FIG. 4A is a plan view illustrating another portion of the memory cell array of the semiconductor device according to this embodiment. FIG. 4B is a cross-sectional view along line A-A′ of FIG. 4A. FIG. 4C is a cross-sectional view along line B-B′ of FIG. 4A.

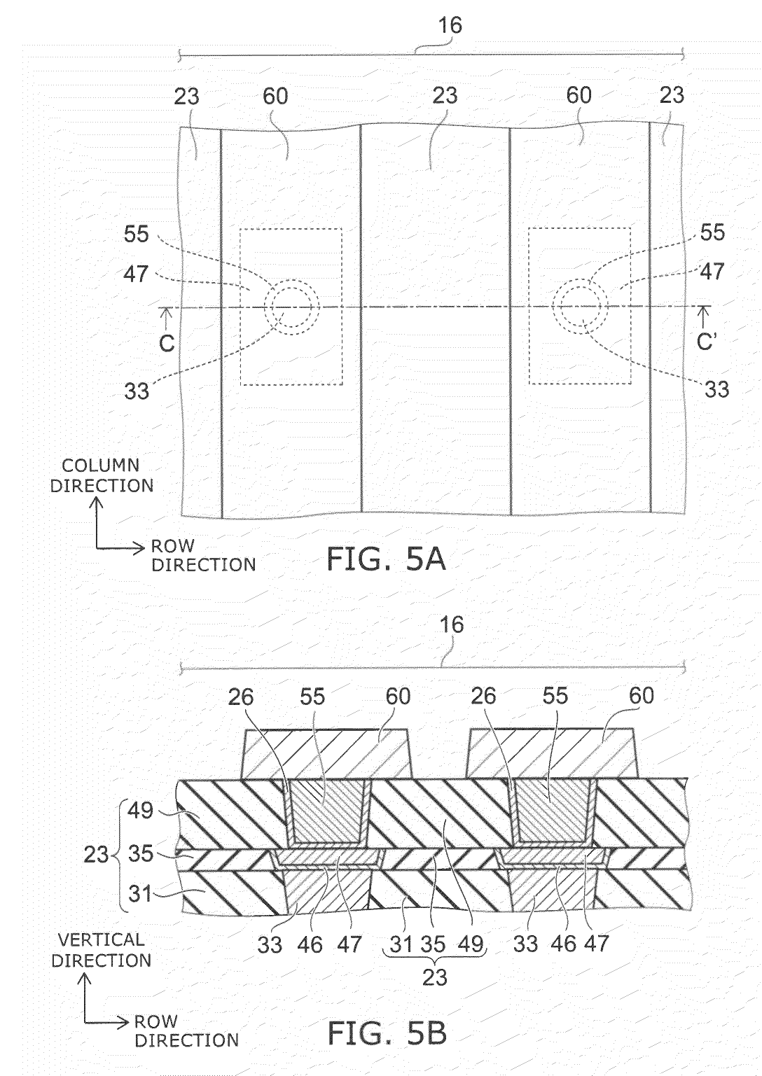

FIG. 5A is a plan view illustrating a portion of a peripheral circuit of the semiconductor device according to this embodiment. FIG. 5B is a cross-sectional view along line C-C′ of FIG. 5A.

As illustrated in FIG. 2, a semiconductor device 11 according to this embodiment is a NAND flash memory. The semiconductor device 11 includes a semiconductor substrate 12 made of, for example, silicon. Herein, two mutually orthogonal directions parallel to the upper face of the semiconductor substrate 12 are taken as a “row direction” and a “column direction.” A memory cell array 13 is disposed on the semiconductor substrate 12. Row decoders 14 are disposed on both row direction sides of the memory cell array 13. A switching region SW, A page buffer 15 and a peripheral circuit 16 are disposed in this order on one side of the memory cell array 13 in the column direction as viewed from the memory cell array 13. A cell well 17 is formed in an upper layer portion of the semiconductor substrate 12 in the memory cell array 13. A shunt region 18 is alternately arranged along the row direction with a memory cell region 19 in the memory cell array 13.

A shunt region 18-1 is alternately arranged along the row direction with a bit line region 19-1 in the page buffer 15. A sense amplifier circuit is disposed on the semiconductor substrate 12 in the page buffer 15. The sense amplifier circuit includes, for example, a plurality of MOSFETs

### (Metal-Oxide-Semiconductor Field-Effect Transistors).

The memory cell array 13 and the page buffer 15 will now be described.

As illustrated in FIGS. 3A to 3C, an inter-layer insulating film 23 made of, for example, silicon oxide is provided on the semiconductor substrate 12. The inter-layer insulating film 23 is omitted in FIG. 2. The contacts 24 and 25 are provided in two levels in the inter-layer insulating film 23 in the shunt region 18, 18-1. Each of the contacts 24 and 25 has a substantially columnar configuration, e.g., an inverted circular-conic trapezoidal configuration, becoming finer downward. The lower end portion of the contact 24 of the lower level is connected to a contact region 20 of the semiconductor substrate 12. On the other hand, the contact 25 of the upper level is provided in a region directly above the contact 24. A barrier metal layer 26 is formed on the lower face of the contact 25 and on the side faces of the contact 25. The barrier metal layer 26 contacts both the contacts 25 and 24. Thereby, the lower end portion of the contact 25 connects the upper end portion of the contact 24 via the barrier metal layer 26. A shunt interconnection 28 is provided as an upper layer interconnection on the inter-layer insulating film 23 in contact with an upper face 25b of the contact 25. The shunt interconnection 28 is aligned in the column direction to pass through a region directly above the contact 25.

A bit line 27 is provided as an intermediate interconnection in the memory cell region 19 and bit line region 19-1. The bit line 27 is aligned in the column direction and is disposed higher than the semiconductor substrate 12 and lower than the shunt interconnection 28. In other words, a lower face 27a of the bit line 27 is positioned higher than a lower face 24a of the contact 24 of the lower level; and an upper face 27b of the bit line 27 is positioned lower than the upper face 25b of the contact 25 of the upper level. For example, the lower face 27a of the bit line 27 is at substantially the same height as an upper face 24b of the contact 24. The bit line 27 has a width and spacing of F corresponding to half of the minimum patterning dimension (2F) determined by the lithography technology. The bit line 27 is not provided in the shunt region 18, 18-1. Accordingly, the bit line 27 is not interposed between the contact 24 and the contact 25 and is isolated from the contacts 24 and 25.

The diffusion coefficient of the conductive material of the contact 24 with respect to the conductive material of the contact 25 is lower than the diffusion coefficient of the conductive material of the bit line 27 with respect to the conductive material of the contact 25. For example, similarly to the first embodiment, the contact 24 is formed of tungsten, the contact 25 is formed of aluminum, the bit line 27 is formed of copper, and the diffusion coefficient of tungsten with respect to aluminum is lower than the diffusion coefficient of copper with respect to aluminum. Similarly to the first embodiment described above, for example, the barrier metal layer 26 is formed of tantalum, tantalum nitride, titanium, or titanium nitride.

As illustrated in FIGS. 3A to 3C, the formation target position of the contact 25 is the region directly above the contact 24. In other words, the contact 25 is formed to match a central axis 25c of the contact 25 with a central axis 24c of the contact 24. If positioned as intended, the entire region of a lower face 25a of the contact 25 is disposed in the region directly above the upper face 24b of the contact 24.

However, as illustrated in FIGS. 4A to 4C, the formation position of the contact 25 may miss the target position due to fluctuation of the manufacturing processes. In such a case, only a portion of the contact 25 is disposed in the region directly above the contact 24; and the remaining portion juts into a region outside the region directly above the contact 24 and extends around onto the side face of the contact 24. On the other hand, the barrier metal layer 26 is not formed easily on the side face of the contact 24. Therefore, the portion of the contact 25 jutting from the region directly above the contact 24 directly contacts the side face of the contact 24 in the region R where the barrier metal layer 26 is not formed.

Multiple memory cells are formed in the memory cell region 19. In other words, multiple element-separating insulators 21 (STI: shallow trench isolation) aligned in the column direction are formed in mutual isolation in the upper layer portion of the cell well 17; and the regions between the element-separating insulators 21 form active areas aligned in the column direction. Floating gate electrodes are arranged along the column direction with a prescribed spacing in the regions directly above the active areas. In other words, the floating gate electrodes are arranged in a matrix configuration along the row direction and the column direction. A control gate electrode aligned in the row direction is provided on the floating gate electrodes to pass through the region directly above the floating gate electrodes. A pair of selection gate electrodes aligned in the row direction is provided on both sides of multiple control gate electrodes formed into a set. A source line contact and a bit line contact are provided outside the pair of selection gate electrodes. The bit line 27 is disposed in the memory cell region 19 on the active area to substantially overlay the active area as viewed from above.

A source line is provided on the source line contact to align in the row direction. The lower end portion of the source line contact is connected to the active area and the upper end portion is connected to the source line. The lower end portion of the bit line contact is connected to the active area and the upper end portion is connected to the bit line 27 described above. Thereby, the floating gate electrode is disposed between the active area and the control gate electrode; and a memory cell is formed at every floating gate electrode. The formation position of the contacts 24 and 25 in the column direction is the same formation position as that of the source line contact and the bit line contact.

The peripheral circuit 16 will now be described.

Similarly to the memory cell array 13, the peripheral circuit 16 as illustrated in FIGS. 5A and 5B includes the inter-layer insulating film 23 provided on the semiconductor substrate 12 (referring to FIG. 3); and an upper layer interconnection 60 is provided on the inter-layer insulating film 23. A contact 33, an intermediate interconnection 47, and a contact 55 are connected between the semiconductor substrate 12 and the upper layer interconnection 60. The contact 33 is provided at substantially the same height as the contact 24 of the memory cell array 13. The intermediate interconnection 47 is provided at substantially the same height as the bit line 27 of the memory cell array 13. The contact 55 is provided at substantially the same height as the contact 25 of the memory cell array 13. The upper layer interconnection 60 is provided at substantially the same height as the shunt interconnection 28 of the memory cell array 13. The width of the intermediate interconnection 47 is wider than the width of the contact 33 and the width of the contact 55 in the row direction.

An insulating film 31, an insulating film 35, and an insulating film 49 are stacked in this order in the inter-layer insulating film 23 from the semiconductor substrate 12 side. The contact 33 is disposed in the insulating film 31. The intermediate interconnection 47 is disposed in the insulating film 35. The contact 55 is disposed in the insulating film 49. In other words, although the contact 24 of the lower level of the memory cell array 13 is connected to the contact 25 of the upper level without an intermediate interconnection interposed therebetween, in the peripheral circuit 16, the contact 33 of the lower level is connected to the contact 55 of the upper level via the intermediate interconnection 47. A barrier metal layer 46 is disposed on the lower face of the intermediate interconnection 47 and on the side faces of the intermediate interconnection 47. The barrier metal layer 26 is disposed on the lower face of the contact 55 and on the side faces of the contact 55. Although an example is illustrated in FIGS. 5A and 5B in which the upper layer interconnection 60 is aligned in the column direction, the upper layer interconnection 60 may be aligned in the row direction.

A method for manufacturing the semiconductor device according to this embodiment will now be described.

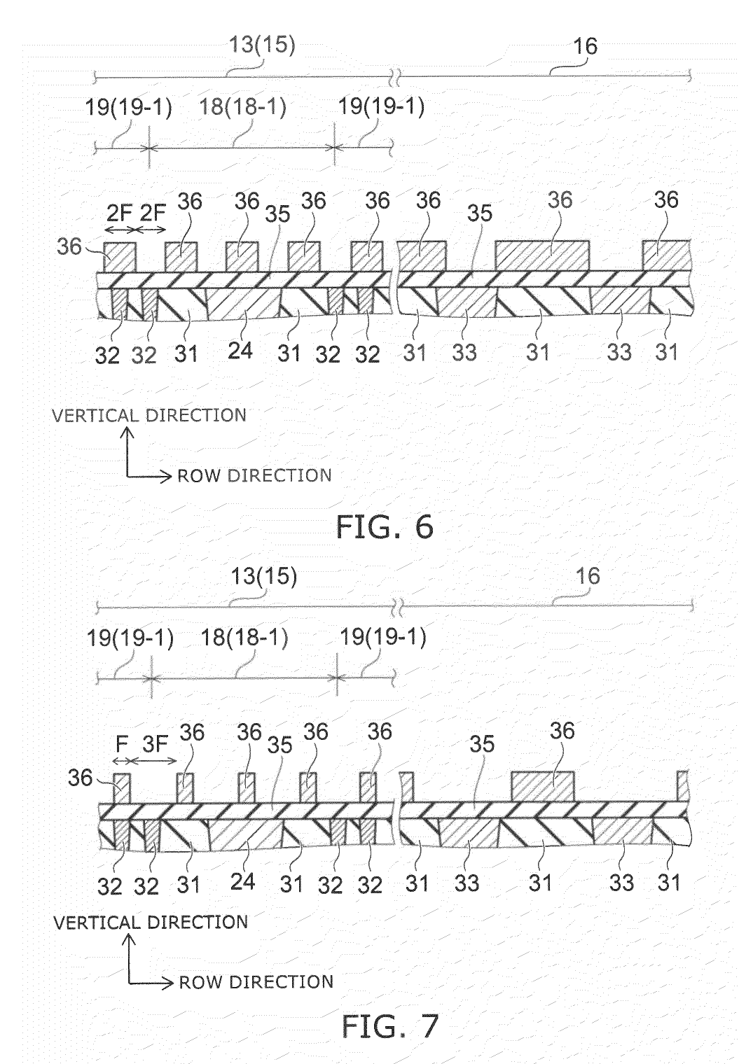

FIG. 6 to FIG. 18 are cross-sectional views of processes, illustrating the method for manufacturing the semiconductor device according to this embodiment. The portion on the left side of each of these drawings illustrates the shunt region and the periphery thereof; and the portion on the right side of each of these drawings illustrates the peripheral circuit region.

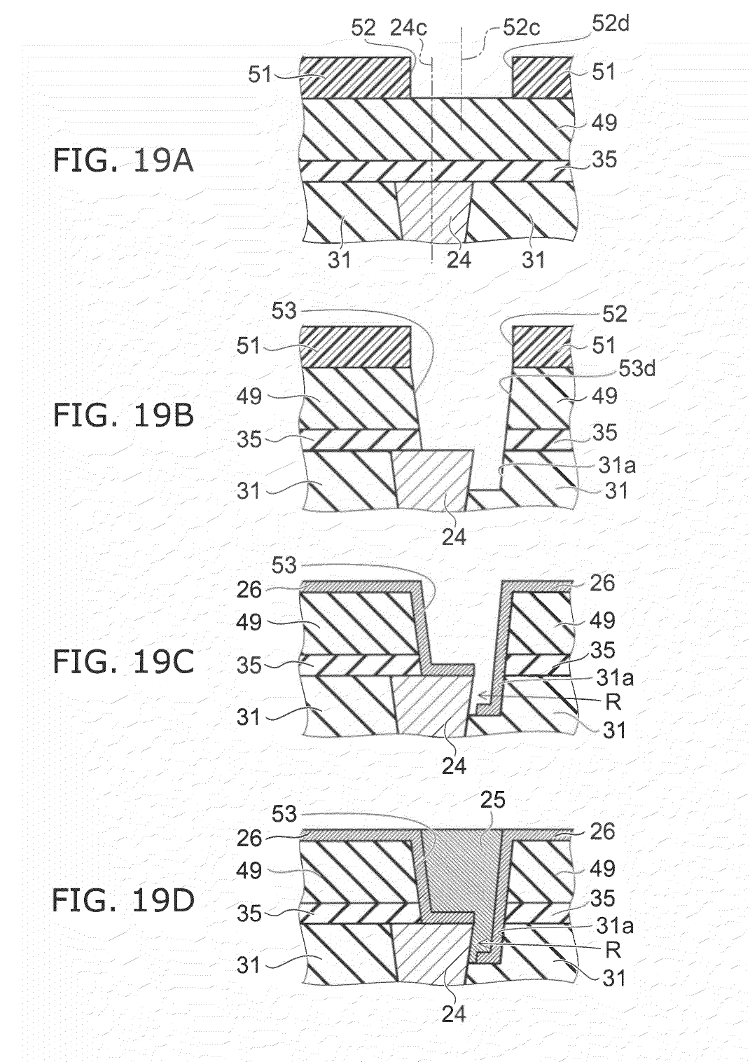

FIGS. 19A to 19D are cross-sectional views of processes, illustrating the method for manufacturing the semiconductor device according to this embodiment in the case where the formation region of the contact 25 is shifted from the region directly above the contact 24.

For convenience of description of the manufacturing method hereinbelow, the region where the memory cell array 13 is to be formed also is referred to as “the memory cell array 13;” and the region where the peripheral circuit 16 is to be formed also is referred to as “the peripheral circuit 16.”

The semiconductor substrate 12 made of, for example, silicon is prepared. Then, an impurity is implanted into a region of the upper layer portion of the semiconductor substrate 12 to form the cell well 17 where the memory cell array 13 is to be formed. The element-separating insulator 21 is formed by making multiple trenches aligned in the column direction in the upper layer portion of the cell well 17 and filling, for example, silicon oxide into the trenches. Thereby, the upper layer portion of the cell well 17 is partitioned into multiple active areas. A floating gate electrode and a control gate electrode are formed on the semiconductor substrate 12. The insulating film 31 made of, for example, silicon oxide is formed to bury the floating gate electrode and the control gate electrode. Contact holes are made in the insulating film 31. By filling tungsten, for example, into the contact holes, the contact 24 is formed in the shunt region 18, 18-1, a contact 32 is formed in the memory cell region 19, and the contact 33 is formed in the peripheral circuit 16. The contact 32, the contact 24, and the contact 33 each have a substantially columnar configuration, e.g., an inverted circular-conic trapezoidal configuration, becoming finer downward.

As illustrated in FIG. 6, silicon oxide, for example, is deposited on the insulating film 31 to form the insulating film 35. Continuing, a mask film 36 is formed by depositing a material, e.g., amorphous silicon, that has etching selectivity with the insulating film 35 by, for example, CVD (chemical vapor deposition) and patterning by lithography and RIE (reactive ion etching). At this time, in the memory cell array 13, pattern having widths and spacings in the row direction of the minimum patterning dimension, i.e., 2F, due to the lithography technology are formed in the mask film 36. In other words, in the memory cell array 13, the arrangement period in the row direction of the patterns of the mask film 36 is 4F. The patterns of the mask film 36 are disposed in a region directly above every other contact 32 of the multiple contacts 32 arranged along the row direction. On the other hand, in the peripheral circuit 16, the mask film 36 is formed to leave the regions directly above the contact 33 exposed and cover the other regions. Accordingly, the pattern width and spacing of the mask film 36 in the peripheral circuit 16 is not limited to 2F.

As illustrated in FIG. 7, slimming of the mask film 36 is performed by, for example, wet etching. Thereby, in the memory cell array 13, the width of each pattern of the mask film 36 is reduced to F. Thereby, the spacing between each pattern of the mask film 36 is increased to 3F. On the other hand, in the peripheral circuit 16, the outer edge of each pattern of the mask film 36 is slightly recessed from the region directly above the contact 33.

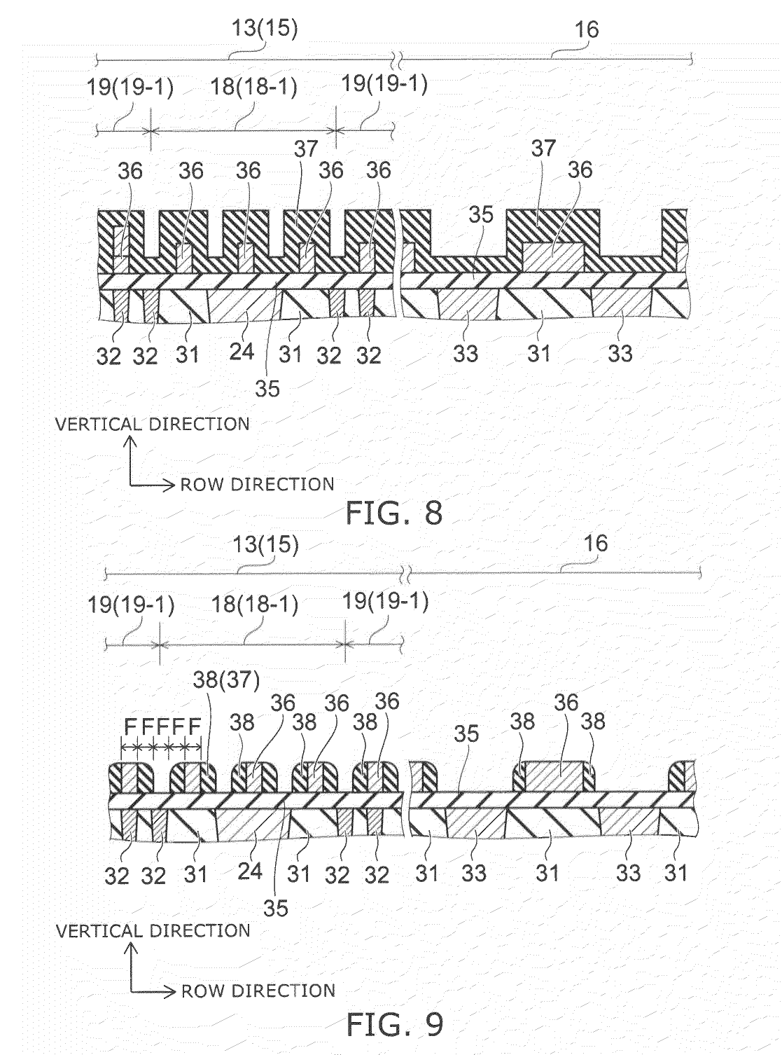

As illustrated in FIG. 8, an insulating film 37 is deposited over the entire surface by, for example, CVD. The insulating film 37 is formed of a material, e.g., silicon nitride, which can ensure etching selectivity with both the material of the insulating film 35 and the material of the mask film 36 and which may be formed with little contamination of the film formation apparatus. At this time, recesses and protrusions are formed in the upper face of the insulating film 37 reflecting the patterns of the mask film 36.

As illustrated in FIG. 9, etch-back of the insulating film 37 is performed by, for example, RIE. Thereby, the insulating film 37 is removed from the upper face of the mask film 36 and from the upper face of the insulating film 35 and remains only or the side faces of each pattern of the mask film 36. Thereby, side walls 38 made of the insulating film 37 are formed on the side faces of each pattern of the mask film 36. The thickness of the side wall 38 in the row direction is F. Thereby, in the memory cell array 13, the distance between the side walls 38 in the row direction also is F.

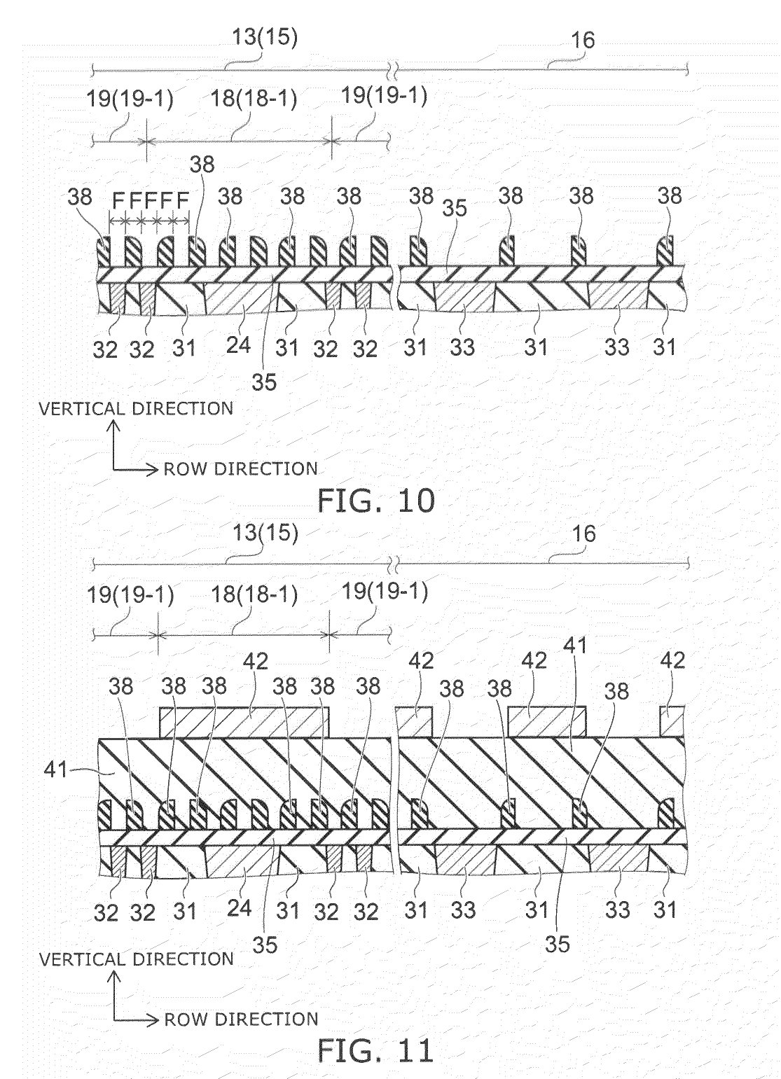

As illustrated in FIG. 10, the mask film 36 (referring to FIG. 8) is removed by, for example, wet etching. Thereby, the side wall 38 remains on the insulating film 35. In the memory cell array 13, the width and spacing of the side wall 38 in the row direction is F. Accordingly, the arrangement period is 2F. On the other hand, in the peripheral circuit 16, the side wall 38 having a thickness of F is left along the outer edge of the region directly above the contact 33.

As illustrated in FIG. 11, an insulating film 41 is deposited over the entire surface by, for example, CVD. The insulating film 41 is formed of a material, e.g., silicon oxide, which can ensure etching selectivity with the side wall 38. A mask film 42 is formed by depositing a mask material on the insulating film 41 and performing patterning by lithography and RIE. The mask film 42 is formed of a material, e.g., amorphous silicon, which can ensure etching selectivity with the insulating film 41. In the memory cell array 13 and the page buffer 15, the mask film 42 covers the shunt region 18, 18-1 and leaves the memory cell region 19 and bit line region 19-1 exposed. In the peripheral circuit 16, the mask film 42 leaves the region directly above the contact 33 exposed and covers the other regions.

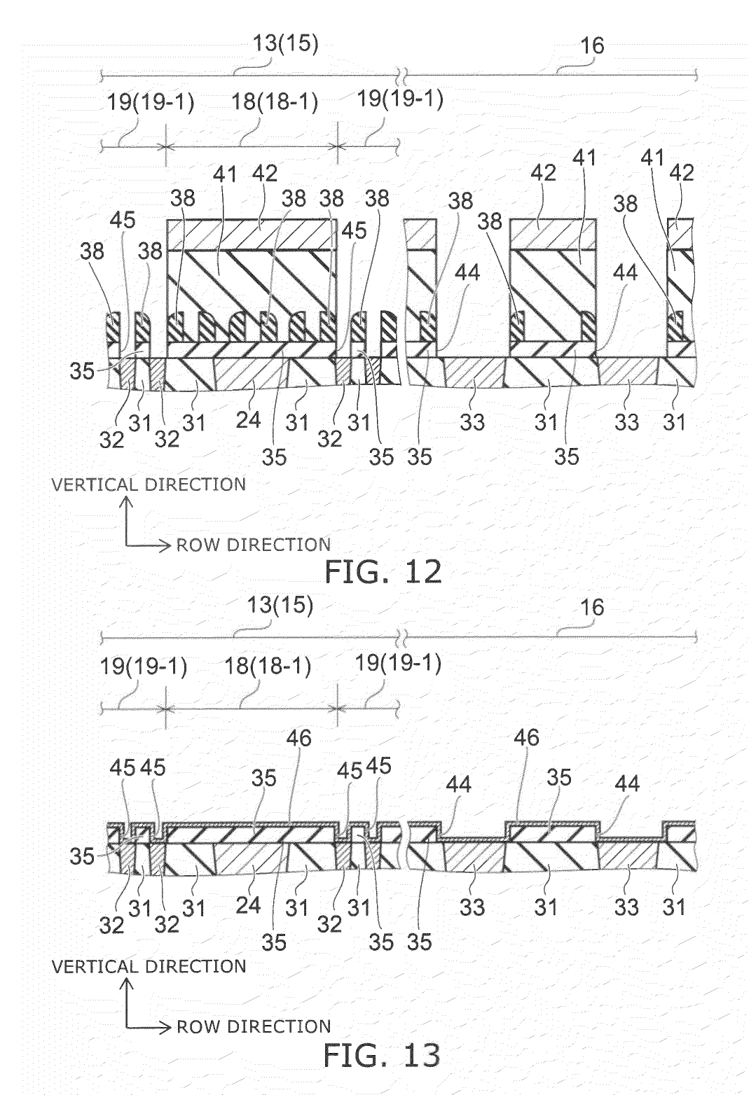

As illustrated in FIG. 12, etching such as, for example, RIE is performed. Thereby, the mask film 42 is used as a mask to selectively remove the insulating film 41. In regions where the insulating film 41 is removed and the side wall 38 is exposed, the side wall 38 is used as a mask to selectively remove the insulating film 35. As a result, the insulating film 41 and the side wall 38 are left in the region directly below the mask film 42. On the other hand, in the regions other than the region directly below the mask film 42, the insulating film 41 is removed. In the regions other than the region directly below the mask film 42, the insulating film 35 is left in the region directly below the side wall 38; and the insulating film 35 is removed in the regions other than the region directly below the side wall 38. As a result, the insulating film 41, the side wall 38, and the insulating film 35 are left in the shunt region 18, 18-1 because the entire shunt region 18, 18-1 is covered with the mask film 42. In the memory cell region 19 and bit line region 19-1, a trench 45 is made aligned in the column direction to pass through the region directly above the contacts 32. The width of the trench 45 is F, i.e., substantially the same as the spacing of the side wall 38. In the peripheral circuit 16, an opening 44 is made in the region directly above the contact 33.

As illustrated in FIG. 13, the mask film 42 (referring to FIG. 12) is removed by, for example, dry etching; and the insulating film 41 and the side wall 38 (referring to FIG. 12) are removed by, for example, wet etching. Continuing, the barrier metal layer 46 is formed by depositing tantalum, tantalum nitride, titanium, or titanium nitride over the entire surface by, for example, CVD or sputtering. At this time, the barrier metal layer 46 is formed not only on the insulating film 35 but also on the inner face of the trench 45 and on the inner face of the opening 44.

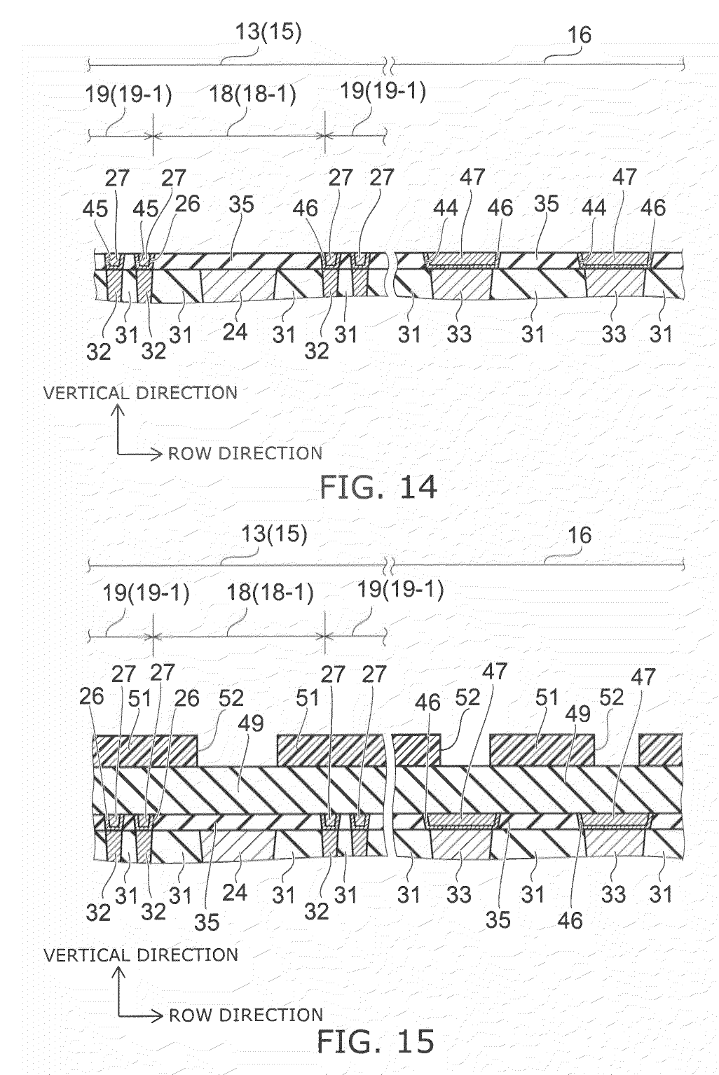

As illustrated in FIG. 14, a conductive material, e.g., a copper layer formed by depositing copper, is formed on the barrier metal layer 46 by, for example, CVD, metal plating, etc. The upper face of the copper layer is planarized by CMP (chemical mechanical polishing) to expose the upper face of the insulating film 35. Thereby, the barrier metal layer 46 and the copper layer are removed from the upper face of the insulating film 35 and are left only in the interiors of the trench 45 and the opening 44. As a result, the barrier metal layer 46 is formed on the inner face of the trench 45 and on the inner face of the opening 44; the bit line 27, i.e., the intermediate interconnection, is formed in the interior of the trench 45; and the intermediate interconnection 47 is formed in the interior of the opening 44. Accordingly, the bit line 27 and the intermediate interconnection 47 are formed of copper. Also, the bit line 27 and the intermediate interconnection 47 are formed at the same height. Restated, it can be said that the bit line 27 and the intermediate interconnection 47 are formed in the same layer.

As illustrated in FIG. 15, the insulating film 49 made of, for example, silicon oxide is deposited by, for example, CVD. Continuing, a resist material is deposited over the entire surface to form a resist film 51. The resist film 51 is patterned by lithography to make openings 52 in the regions directly above the contacts 24 and 33. It is taken that the configuration, as viewed from above, of the opening 52 made in the region directly above the contact 24 is, for example, circular. At this time, as illustrated in FIG. 19A, a central axis 52c of the opening 52 made in the region directly above the contact 24 may undesirably shift from the central axis 24c of the contact 24; and an outer edge 52d of the opening 52 may be undesirably positioned outside the contact 24 as viewed from above.

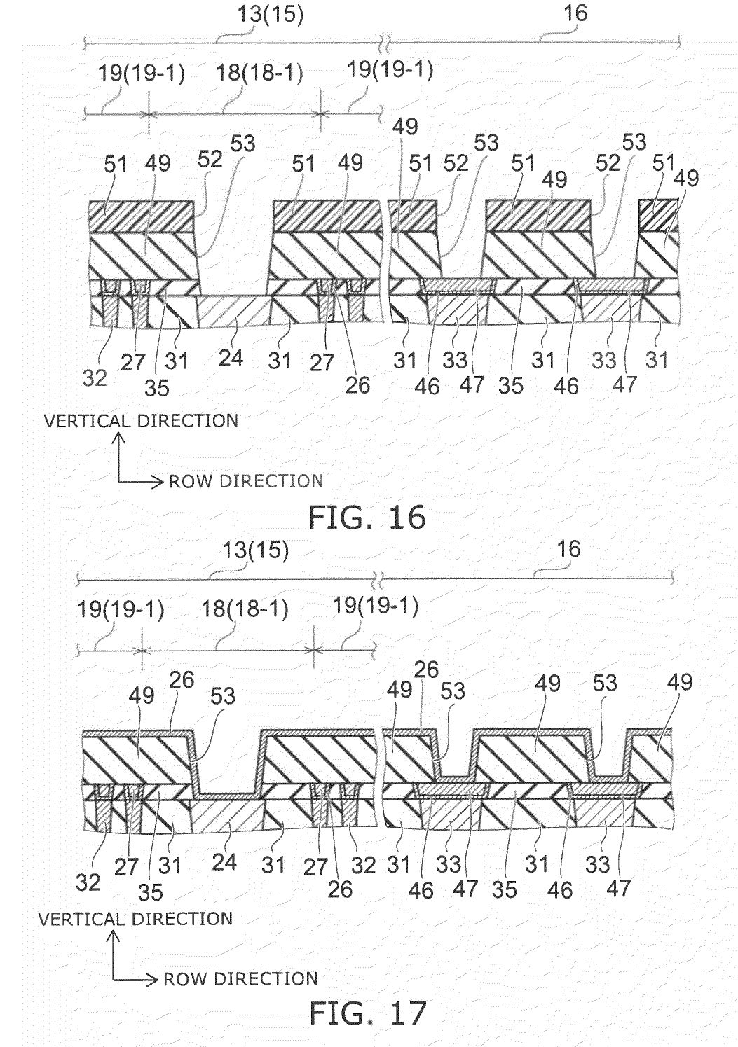

As illustrated in FIG. 16, the resist film 51 is used as a mask to perform etching by, for example, RIE. Thereby, the insulating film 49 and the insulating film 35 are removed from the portion corresponding to the region directly below the opening 52 to make an opening 53. The resist film 51 is removed. The upper face of the contact 24 and the upper face of the intermediate interconnection 47 are exposed at the bottom faces of the openings 53. Although the distance from the upper end (the upper face of the insulating film 49) to the lower end (the lower face of the insulating film 35) of the opening 53 of the memory cell array 13 differs from the distance from the upper end (the upper face of the insulating film 49) to the lower end (the lower face of the insulating film 49) of the opening 53 of the peripheral circuit 16, the opening 53 can be made stably in both the memory cell array 13 and the peripheral circuit 16 by performing etching that uses the contact 24 and the intermediate interconnection 47 as stoppers. This is because the contact 24 and the intermediate interconnection 47 are made of metal and can easily provide an etching ratio with the insulating film 49 and the insulating film 35 which are formed of insulating materials.

At this time, in the case where the outer edge 52d of the opening 52 of the resist film 51 juts from the region directly above the contact 24 as illustrated in FIG. 19B, an outer edge 53d of the opening 53 also may undesirably jut from the region directly above the contact 24; and a portion of the insulating film 31 positioned to the side of the contact 24 is dug out. As a result, a dug-out portion 31a is made in the insulating film 31. In particular, the dug-out portion 31a is made easily in the case where the insulating film 35 and the insulating film 31 are formed of the same material or in the case where the etching rate of the insulating film 31 is higher than the etching rate of the insulating film 35.

As illustrated in FIG. 17, the barrier metal layer 26 is formed by depositing a conductive material such as tantalum, tantalum nitride, titanium, or titanium nitride over the entire surface by, for example, CVD, sputtering, etc. The barrier metal layer 26 is formed not only on the upper face of the insulating film 49 but also on the upper face of the opening 53. At this time, in the case where the dug-out portion 31a is made in the insulating film 31 as illustrated in FIG. 19B, the barrier metal layer 26 is formed on the bottom face and the side face of the dug-out portion 31a but is not easily formed on the side face of the contact 24 as illustrated in FIG. 19C. This is because the configuration of the contact 24 becomes finer downward, the side faces of the contact 24 are inclined with respect to the perpendicular direction such that the upper portion juts toward the interior of the dug-out portion 31a, and the conductive material of the barrier metal layer 26 does not easily extend around. The barrier metal layer 26 does not extend around easily particularly when formed using sputtering having poor coverage. As a result, the region R occurs in the region where the side face of the contact 24 is not covered with the barrier metal layer 26 and exposed in the dug-out portion 31a.

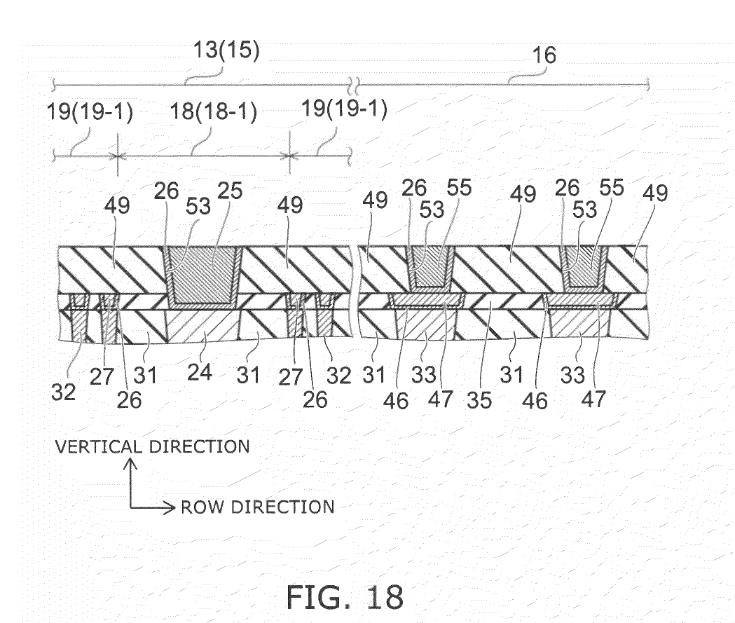

As illustrated in FIG. 18, an aluminum layer is deposited over the entire surface by, for example, CVD and the upper face is planarized by CMP. Thereby, the aluminum layer and the barrier metal layer 26 are removed from the insulating film 49 and are left only in the opening 53. As a result, the contact 25 made of aluminum is formed in the opening 53 in the memory cell array 13; and the contact 55 made of aluminum is formed in the opening 53 in the peripheral circuit 16. The contact 25 is connected to the contact 24 via the barrier metal layer 26; and the contact 55 is connected to the contact 33 via the barrier metal layer 26, the intermediate interconnection 47, and the barrier metal layer 46. In case of FIG. 19C, as illustrated in FIG. 19D, the contact 25 made of aluminum is in direct contact with the contact 24 made of tungsten at the region R.

As illustrated in FIGS. 3A to 3C, an aluminum layer is deposited over the entire surface of the insulating film 49 by, for example, CVD. Then, the aluminum layer is patterned by, for example, lithography and RIE. Thereby, in the memory cell array 13 and the page buffer 15, the shunt interconnection 28 is formed on the insulating film 49 to align in the column direction and pass through the region directly above the contacts 25. The lower face of the shunt interconnection 28 contacts the upper face of the contact 25. Thereby, the shunt interconnection 28 is connected to the cell well 17 of the semiconductor substrate 12 via the contact 25, the barrier metal layer 26, and the contact 24. On the other hand, in the peripheral circuit 16, the upper layer interconnection 60 is formed on the insulating film 49 to align in the column direction and pass through the region directly above the contacts 55. The lower face of the upper layer interconnection 60 contacts the upper face of the contact 55. Thereby, the upper layer interconnection 60 is connected to the semiconductor substrate 12 via the contact 55, the barrier metal layer 26, the intermediate interconnection 47, the barrier metal layer 46, and the contact 33. Thus, the semiconductor device 11 is manufactured. In such a case, the stacked film made of the insulating films 31, 35, and 49 forms the inter-layer insulating film 23.

Effects of this embodiment will now be described.

According to this embodiment, similarly to the first embodiment described above, the semiconductor device 11 can be shrunk because no intermediate interconnection having a width wider than the contact 24 as viewed from above is provided between the contact 24 and the contact 25.

In the case where the formation position of the opening 52 is shifted from the region directly above the contact 24 as illustrated in FIG. 19A during the manufacturing process of the semiconductor device 11 illustrated in FIG. 15, the contact 25 may therefore contact the contact 24 as illustrated in FIG. 19D during the process illustrated in FIG. 18. In such a case as well, in this embodiment, the diffusion coefficient of the conductive material (e.g., tungsten) of the contact 24 with respect to the conductive material (e.g., aluminum) of the contact 25 is lower than the diffusion coefficient of the conductive material (e.g., copper) of the intermediate interconnection 47 with respect to the conductive material (e.g., aluminum) of the contact 25. Therefore, the diffusion of the conductive material (e.g., tungsten) of the contact 24 into the contact 25 can be suppressed. Therefore, the occurrence of voids in the contact 24 can be suppressed; and the formation of high-resistance intermetallic compounds due to reactions between the conductive material (e.g., tungsten) of the contact 24 and the conductive material (e.g., tantalum or titanium) of the barrier metal layer 26 can be suppressed. As a result, the increase of the resistance between the contact 24 and the contact 25 can be prevented.

Also in this embodiment, copper, which has an electrical resistivity lower than that of aluminum, can be used as the material of the bit line 27 and the intermediate interconnection 47. As a result, the increase of the resistance between the contact 24 and the contact 25 can be prevented while reducing the resistance of the bit line 27 and the intermediate interconnection 47. Therefore, the characteristics of the semiconductor device 11 can be improved.

In the peripheral circuit 16, the contact 33 of the lower level is connected to the contact 55 of the upper level via the intermediate interconnection 47. Thereby, one or multiple contacts 33 can be connected to one or multiple contacts 55 via the intermediate interconnection 47; and the circuit elements can be connected to each other in complex ways. Even in the case where the central axis of the contact 33 has a large shift amount from the central axis of the contact 55 as illustrated in FIG. 1D, there is little possibility that the formation position of the contact 55 will be outside the region directly above the intermediate interconnection 47. Circumstances in the peripheral circuit 16 include, for example, a gate electrode having a wide width being formed between adjacent contacts 33, etc.; and compared to the memory cell array 13, there are few requirements to reduce the spacing between adjacent intermediate interconnections 47. Therefore, the intermediate interconnections 47 may be disposed with widths wider than the widths of the bit lines 27. On the other hand, compared to the memory cell array 13 and the page buffer 15, the peripheral circuit 16 may include connecting the circuit elements to each other in complex ways. Thus, according to this embodiment, the intermediate interconnection between the contacts can be excluded to reduce the circuit surface area in the memory cell array 13 and the page buffer 15; and the intermediate interconnection can be provided between the contacts to branch the current path in the peripheral circuit 16.

Also in this embodiment, the contact 25 of the upper level of the shunt region 18 is formed simultaneously with the contact 55 of the peripheral circuit 16. Therefore, the number of processes does not increase due to the contact 25 being formed. Accordingly, the manufacturing cost of the semiconductor device 11 does not increase.

A third embodiment of the invention will now be described.

This embodiment is another method for manufacturing the semiconductor device according to the second embodiment described above.

In this embodiment, the method of patterning the peripheral circuit 16 differs from that of the second embodiment described above. The method of patterning the memory cell array 13 is similar to that of the second embodiment.

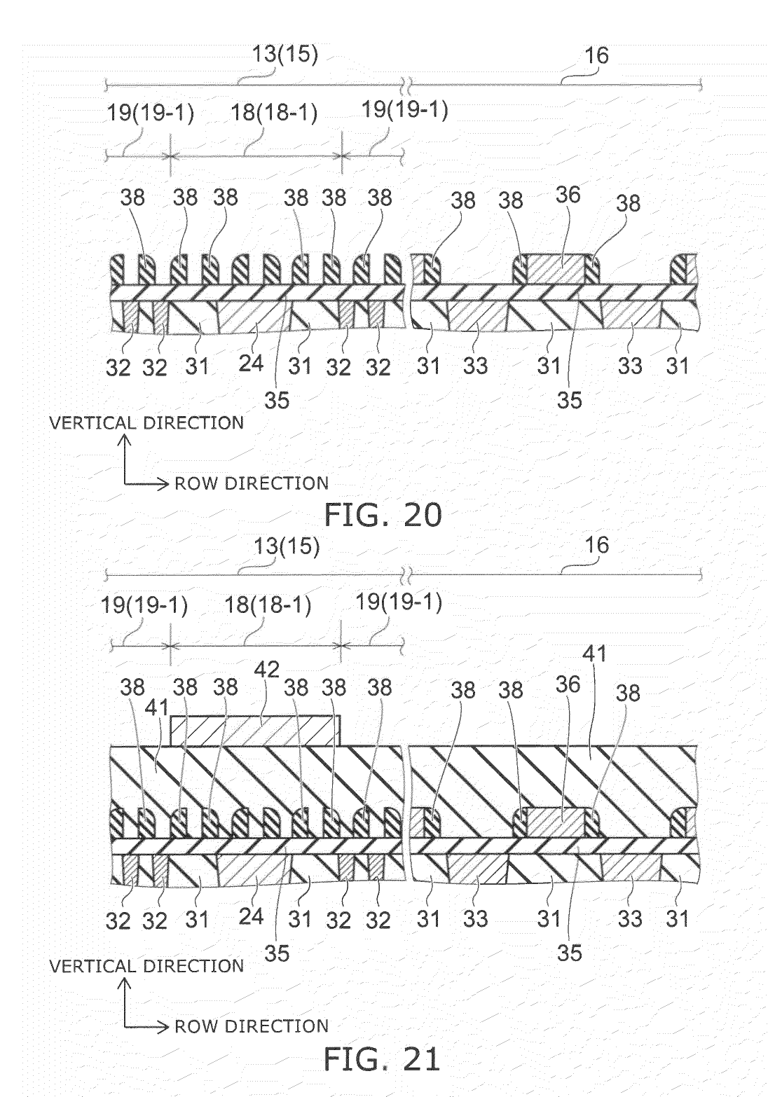

FIG. 20 to FIG. 22 are cross-sectional views of processes, illustrating the method for manufacturing the semiconductor device according to this embodiment. The portion on the left side of each of these drawings illustrates the shunt region and the periphery thereof; and the portion on the right side of each of these drawings illustrates the peripheral circuit region.

The structural body illustrated in FIG. 9 is constructed by the processes illustrated in FIG. 6 to FIG. 9 described above.

As illustrated in FIG. 20, the mask film 36 is removed from shunt region 18 and the memory cell region 19 in the memory cell array 13 and, shunt region 18-1 and bit line region 19-1 in the page buffer 15. Thereby, in the memory cell array 13 and the page buffer 15, the side wall 38 is left on the insulating film 35; and the width and spacing of the side wall 38 in the row direction is F. At this time, the mask film 36 remains in the peripheral circuit 16.

As illustrated in FIG. 21, the insulating film 41 made of, for example, silicon oxide is deposited on the entire surface. The mask film 42 made of, for example, amorphous silicon is formed on the insulating film 41. In the memory cell array 13, the mask film 42 is formed to cover the shunt region 18 and leave the memory cell region 19 exposed. At this time, the mask film 42 is not formed in the peripheral circuit 16.

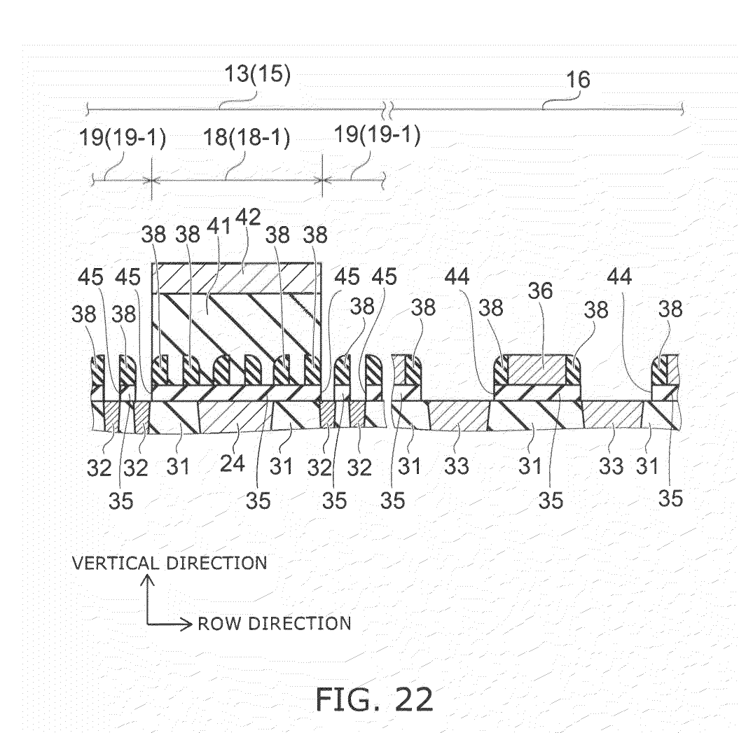

As illustrated in FIG. 22, etching is performed by, for example, RIE. Thereby, in the memory cell array 13, the mask film 42 and the side wall 38 are used as masks to selectively remove the insulating film 41 and the insulating film 35. As a result, the insulating film 41, the side wall 38, and the insulating film 35 remain as-is in the shunt region 18; and the trench 45 is made in the memory cell region 19. On the other hand, in the peripheral circuit 16, the opening 44 is made by using the side wall 38 and the mask film 36 as masks to remove portions of the insulating film 35 not covered with the side wall 38 and the mask film 36. The mask film 42 is removed by, for example, dry etching; and the insulating film 41 and the side wall 38 are removed by, for example, wet etching. The subsequent processes are similar to the processes illustrated in FIG. 13 to FIG. 18. Also according to this embodiment, the semiconductor device 11 can be manufactured similarly to the second embodiment described above. Otherwise, the manufacturing methods and effects of this embodiment are similar to those of the second embodiment described above.

As described above, according to the embodiments of the invention, a downsizable semiconductor device and a method for manufacturing the same can be realized.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modification as would fall within the scope and spirit of the inventions.

1. A semiconductor device, comprising:
a first contact formed of a first conductive material;
a second contact formed of a second conductive material, a lower face portion of the second contact being connected to an upper face portion of the first contact; and
an intermediate interconnection formed of a third conductive material and isolated from the first contact and the second contact, a lower face of the intermediate interconnection being positioned higher than a lower face of the first contact, an upper face of the intermediate interconnection being positioned lower than an upper face of the second contact,
a diffusion coefficient of the first conductive material with respect to the second conductive material being lower than a diffusion coefficient of the third conductive material with respect to the second conductive material.

2. The device according to claim 1, further comprising a barrier metal layer disposed between an upper face of the first contact and a lower face of the second contact to suppress diffusion of the first conductive material into the second contact.

3. The device according to claim 1, wherein the first conductive material is tungsten, the second conductive material is aluminum, and the third conductive material is copper.

4. The device according to claim 3, further comprising a barrier metal layer disposed between an upper face of the first contact and a lower face of the second contact, the barrier metal layer being made of tantalum, tantalum nitride, titanium, or titanium nitride.

5. The device according to claim 1, wherein a portion of the second contact is disposed in a region directly above the first contact, a remaining portion of the second contact is disposed in a region outside the region directly above the first contact, and a side face of the remaining portion is in contact with a side face of the first contact.

6. The device according to claim 1, further comprising:
a semiconductor substrate connected to a lower end portion of the first contact;
a first insulating film provided on the semiconductor substrate, the first contact being disposed in the first insulating film,
a second insulating film provided on the first insulating film, a lower portion of the second contact and the intermediate interconnection being disposed in the second insulating film;
a third insulating film provided on the second insulating film, an upper portion of the second contact being disposed in the third insulating film;
an upper layer interconnection provided on the third insulating film to connect to an upper end portion of the second contact;
a third contact provided in the first insulating film;
one other intermediate interconnection provided in a region of the second insulating film including a region directly above the third contact;
a fourth contact provided in a portion of a region of the third insulating film directly above the one other intermediate interconnection; and
one other upper layer interconnection provided on the third insulating film to connect to an upper end portion of the fourth contact.

7. The device according to claim 6, wherein:
the device is a NAND nonvolatile semiconductor memory device;
the upper layer interconnection is a shunt interconnection to apply a potential to the semiconductor substrate; and
the intermediate interconnection is a bit line.

8. The device according to claim 7, further comprising a fifth contact provided in the first insulating film, a lower end portion of the fifth contact being connected to the semiconductor substrate, an upper end portion of the fifth contact being connected to the intermediate interconnection.

9. The device according to claim 1, wherein the first contact and the second contact have columnar configurations becoming finer downward.

10. A semiconductor device, comprising:
a first contact formed of tungsten;
a second contact formed of aluminum, a lower end portion of the second contact being connected to an upper end portion of the first contact; and
an intermediate interconnection formed of copper and isolated from the first contact and the second contact, a lower face of the intermediate interconnection being positioned higher than a lower face of the first contact, an upper face of the intermediate interconnection being positioned lower than an upper face of the second contact.

11. The device according to claim 10, further comprising a barrier metal layer disposed between an upper face of the first contact and a lower face of the second contact, the barrier metal layer being made of tantalum, tantalum nitride, titanium, or titanium nitride.

12. The device according to claim 10, wherein a portion of the second contact is disposed in a region directly above the first contact, a remaining portion of the second contact is disposed in a region outside the region directly above the first contact, and a side face of the remaining portion is in contact with a side face of the first contact.

13. The device according to claim 10, further comprising:
a semiconductor substrate connected to a lower end portion of the first contact;
a first insulating film provided on the semiconductor substrate, the first contact being disposed in the first insulating film;
a second insulating film provided on the first insulating film, a lower portion of the second contact and the intermediate interconnection being disposed in the second insulating film;
a third insulating film provided on the second insulating film, an upper portion of the second contact being disposed in the third insulating film;
an upper layer interconnection provided on the third insulating film to connect to an upper end portion of the second contact;
a third contact provided in the first insulating film;
one other intermediate interconnection provided in a region of the second insulating film including a region directly above the third contact;
a fourth contact provided in a portion of a region of the third insulating film directly above the one other intermediate interconnection; and
one other upper layer interconnection provided on the third insulating film to connect to an upper end portion of the fourth contact.

14. The device according to claim 13, wherein:
the device is a NAND nonvolatile semiconductor memory device;
the upper layer interconnection is a shunt interconnection to apply a potential to the semiconductor substrate; and
the intermediate interconnection is a bit line.

15. The device according to claim 14, further comprising a fifth contact provided in the first insulating film, a lower end portion of the fifth contact being connected to the semiconductor substrate, an upper end portion of the fifth contact being connected to the intermediate interconnection.

16. The device according to claim 10, wherein the first contact and the second contact have columnar configurations becoming finer downward.

17. A method for manufacturing a semiconductor device, comprising:
forming a first contact formed of a first conductive material in a first insulating film;
forming a second insulating film on the first insulating film;
forming an intermediate interconnection formed of a third conductive material in a portion of the second insulating film isolated from a region directly above the first contact;
forming a third insulating film on the second insulating film;
forming a second contact formed of a second conductive material in a portion of the second insulating film and the third insulating film including a region directly above the first contact,
a diffusion coefficient of the first conductive material with respect to the second conductive material being lower than a diffusion coefficient of the third conductive material with respect to the second conductive material.

18. The method according to claim 17, wherein the forming of the second contact includes:
making an opening by removing a portion of the second insulating film and the third insulating film including a region directly above the first contact;
forming a barrier metal layer on an inner face of the opening; and
filling the second conductive material into the opening.

19. The method according to claim 17, comprising:
forming, during the forming of the first contact, a third contact formed of the first conductive material in the first insulating film;
forming, during the forming of the intermediate interconnection, one other intermediate interconnection formed of the third conductive material in a portion of the second insulating film including a region directly above the third contact; and
forming, during the forming of the second contact, a fourth contact formed of the second conductive material in a portion of a region of the third insulating film directly above the one other intermediate interconnection.
